(19) United States
(12) Patent Application Publication
(10) Pub. No.: US 2012/0112368 A1
(43) Pub. Date: May 10, 2012

(54) MEMS SENSOR PACKAGE

(75) Inventors: Yukihiro GORAI, Niigata-ken (JP); Koji NISHIMURA, Niigata-ken (JP); Takayuki MINAGAWA, Niigata-ken (JP); Masaru SAKURAI, Niigata-ken (JP)

(73) Assignee: ALPS ELECTRIC CO., LTD., Tokyo (JP)

(21) Appl. No.: 13/348,569

(22) Filed: Jan. 11, 2012

Related U.S. Application Data
(63) Continuation of application No. PCT/JP2010/063243, filed on Aug. 5, 2010.

(30) Foreign Application Priority Data
Aug. 11, 2009 (JP) 2009-186598

(51) Int. Cl. H01L 23/485

(52) U.S. Cl. 257/782; 257/E23.02

(57) ABSTRACT

An MEMS sensor package includes an MEMS sensor and a driving IC that controls driving of the MEMS sensor, which are fixed onto the same mounting surface made of a given package material, wherein an MEMS sensor mounting area and a driving IC mounting area are set on the mounting surface, a die attach metalized layer is formed on a package material of the driving IC mounting area, the driving IC is mounted on the die attach metalized layer, and the MEMS sensor is mounted on a package material of the MEMS sensor mounting area.

### CLAIM OF PRIORITY

This application is a Continuation of International Application No. PCT/JP2010/063243 filed on Aug. 5, 2010, which claims benefit of Japanese Patent Application No. 2009-186598 filed on Aug. 11, 2009. The entire contents of each application noted above are hereby incorporated by reference.

### BACKGROUND OF THE INVENTION

1. Field of the Invention

The present invention relates to an MEMS sensor package having an MEMS sensor and a driving IC on the same mounting surface.

2. Description of the Related Art

In recent years, an MEMS sensor using MEMS (Micro Electro Mechanical Systems) has been attracting attention in many fields of technology such as an accelerometer, optical communications, and biomedical systems.

Usually, the MEMS sensor is sealed by a resin material in a state where it is mounted on the same mounting surface as that of a driving IC that controls driving of the MEMS sensor, thereby turning into an MEMS sensor package, and is mounted on a circuit substrate in the state of being the MEMS sensor package. In an existing MEMS sensor package, the MEMS sensor and the driving IC are directly adhered and fixed to a mounting surface, alternatively, a mounting surface is overall subjected to die attach metallization working and the MEMS sensor and the driving IC are then adhered and fixed onto a die attach metalized layer. A technique of joining the MEMS sensor or a sensor substrate through a die attach metalized layer is described in Japanese Unexamined Patent Application Publication No. 60-37753, Japanese Unexamined Patent Application Publication No. 1-206228, and Japanese Unexamined Patent Application Publication No. 4-25736, for example.

However, if the entire mounting surface is die-attach-metalized, since the driving IC can be earthed to a ground through the die attach metalized layer, it is not affected by external noise, which is desirable. On the other hand, with respect to the MEMS sensor having an ultrafine-fabricated movable portion, since the die attach metalized layer made of a metal material has extremely-high linear expansion coefficient compared to the MEMS sensor, it is found that the MEMS sensor receives thermal strain stress on the package side which arises at the time of mounting of the MEMS sensor, so that sensor performance is deteriorated. On the contrary, in a case where the MEMS sensor and the driving IC are directly adhered and fixed to the mounting surface without being provided with the die attach metalized layer, although deterioration in the performance of the MEMS sensor is small, the driving IC is easily affected by external noise, which is undesirable.

### SUMMARY OF THE INVENTION

The present invention provides a high-performance MEMS sensor package without deteriorating in the performance of an MEMS sensor which is mounted on the same mounting surface as that of a driving IC.

The present invention has been made focusing on the fact that the influence of external noise on a driving IC is reduced by grounding a driving IC mounting area through a die attach metalized layer and thermal strain stress which is applied to an MEMS sensor is suppressed by making a die attach metalized layer not provided on an MEMS sensor mounting area, so that a deterioration in sensor performance is prevented.

That is, according to an aspect of the invention, there is provided an MEMS sensor package including: an MEMS sensor and a driving IC that controls driving of the MEMS sensor, which are fixed to the same mounting surface made of a given package material, wherein an MEMS sensor mounting area and a driving IC mounting area are set on the mounting surface, a die attach metalized layer is formed on a package material of the driving IC mounting area, the driving IC is mounted on the die attach metalized layer, and the MEMS sensor is mounted on a package material of the MEMS sensor mounting area. It is preferable that the die attach metalized layer be connected to a ground in order to reduce external noise on the driving IC. It is preferable that the package material be a material having an equivalent linear expansion coefficient to that of a base material of the MEMS sensor. Here, the equivalent linear expansion coefficient to that of a base material of the MEMS sensor means that the difference between it and the linear expansion coefficient of a base material of the MEMS sensor is within 5 ppm/° C. In particular, if the package material and the base material of the MEMS sensor are set to be the same, there is no difference in linear expansion coefficient between the MEMS sensor and the package, so that thermal strain stress which is applied to the MEMS sensor at the time of mounting of the MEMS sensor can be further reduced.

### BRIEF DESCRIPTION OF THE DRAWINGS

FIG. 1 is an exploded perspective view showing the overall configuration of an MEMS sensor package related to an embodiment of the invention in a state of being divided into a main body section and a lid member;

FIG. 2 is a plan view showing the main body section of the MEMS sensor package when viewed from the upper surface side;

FIG. 3 is a cross-sectional view along line III-III of FIG. 2;

FIG. 4 is a cross-sectional view along line IV-IV of FIG. 2;

FIG. 5 is a cross-sectional view along line V-V of FIG. 2; and

FIG. 6 is a plan view showing the main body section before an MEMS sensor and a driving IC are mounted, when viewed from the upper surface side.

### DESCRIPTION OF THE PREFERRED EMBODIMENTS

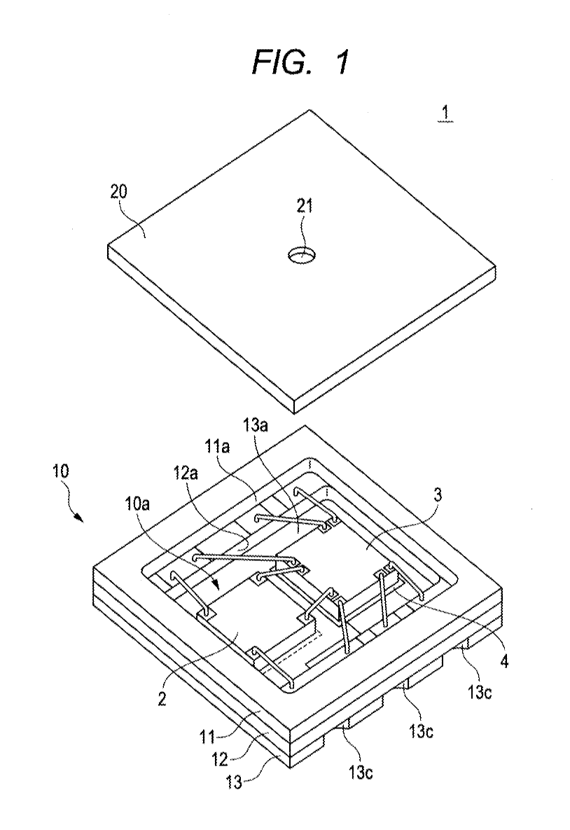

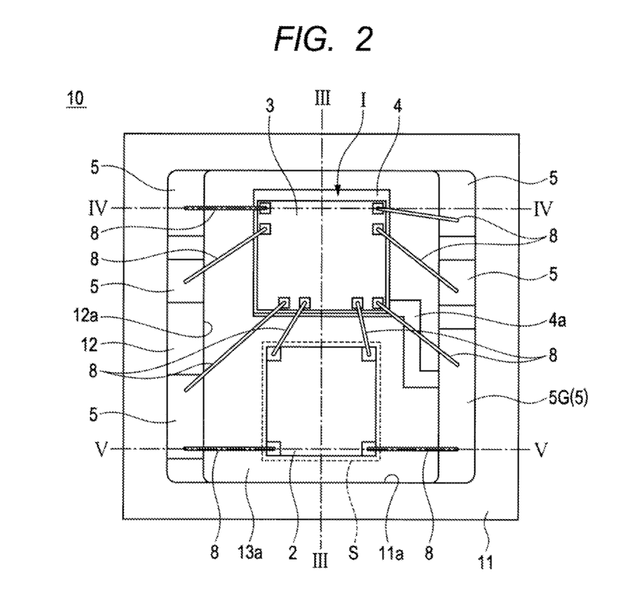

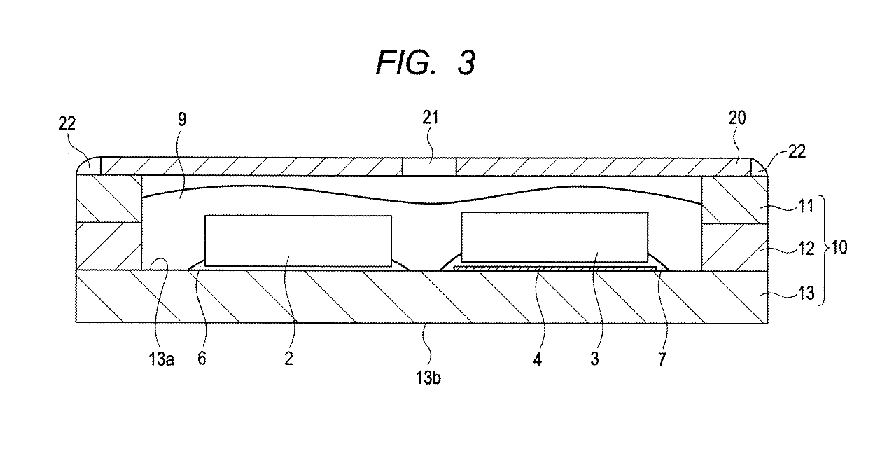

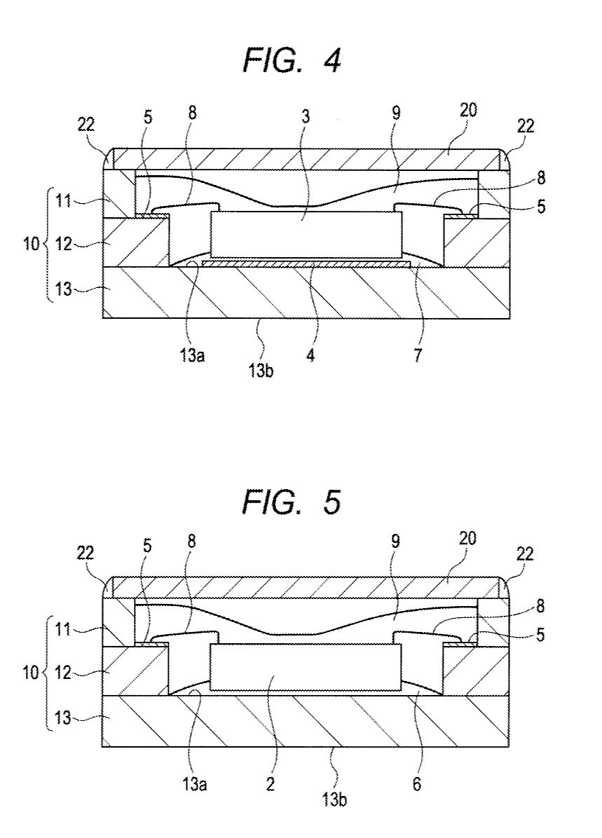

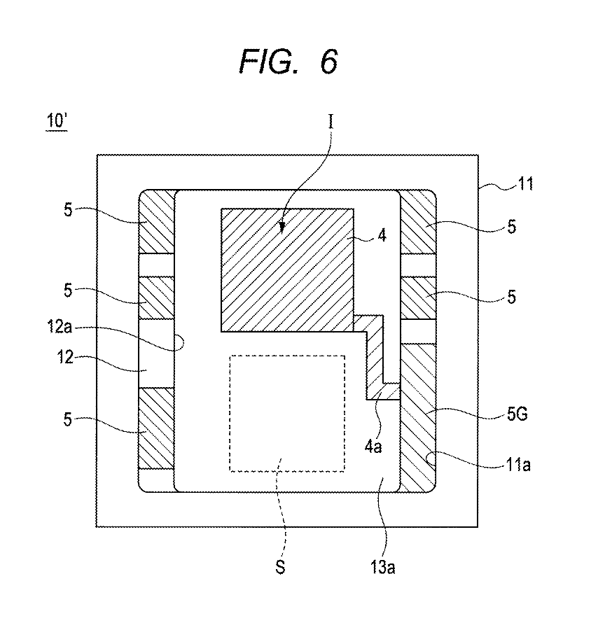

FIGS. 1 to 6 show an MEMS sensor package related to an embodiment of the invention. FIG. 1 is an exploded perspective view showing an MEMS sensor package 1, FIG. 2 is a plan view showing a main body section 10 of the MEMS sensor package 1 when viewed from the upper surface side, FIG. 3 is a cross-sectional view along line III-III of FIG. 2, FIG. 4 is a cross-sectional view along line IV-IV of FIG. 2, FIG. 5 is a cross-sectional view along line V-V of FIG. 2, and FIG. 6 is a plan view showing a main body section 10′ before an MEMS sensor and a driving IC are mounted, when viewed from the upper surface side. In FIGS. 1 and 2, a sealing resin is omitted.

The MEMS sensor package 1 includes a box-shaped main body section 10 having a receiving concave portion 10a for receiving an MEMS sensor 2 and a driving IC 3, and a lid member 20 which covers the receiving concave portion 10a of the main body section 10. The lid member 20 has, at the center thereof, a circular hole 21 which makes the inside and the outside of the main body section 10 be communicated with each other, and a peripheral edge portion is adhered and fixed to the upper surface of the main body section 10 over the entire periphery by a resin adhesive 22.

The main body section 10 is constituted by laminating a first substrate 11 that is an uppermost layer and has at the center thereof an opening portion 11 a having an approximately square planar shape, a second substrate 12 that is an intermediate layer and has at the center thereof an opening portion 12a having an approximately rectangular planar shape, in which one of the vertical and horizontal dimensions is smaller than that of the opening portion 11a of the first substrate 11, and a third substrate 13 that is the flat lowermost layer having no macroscopic irregularities, warpage, or cutout on the surface of the substrate. The receiving concave portion 10a is formed by the opening portion 11a of the first substrate 11 and the opening portion 12a of the second substrate 12, and the portion of the third substrate 13, which is exposed from the receiving concave portion 10a (specifically, the opening portion 12a of the second substrate 12), becomes a mounting surface 13a for the MEMS sensor 2 and the driving IC 3. The main body section 10 may be constituted by the laminated substrates, as in this embodiment, and may also be constituted by forming the receiving concave portion 10a in a single substrate.

On the mounting surface 13a, an MEMS sensor mounting area S having a rectangular planar shape corresponding to the shape of the mounting surface of the MEMS sensor 2 and a driving IC mounting area I having a rectangular planar shape corresponding to the shape of the mounting surface of the driving IC 3 are provided adjacent to each other to the extent of allowing wire bonding to be performed, as shown in FIG. 6. In the mounting surface 13a, on the driving IC mounting area I, a die attach metalized layer 4 made of, for example, gold or copper is formed slightly larger than the driving IC mounting area I. A portion 4a of the die attach metalized layer 4 is extended up to an electrode pad 5G which is connected to a ground terminal, and connected to a ground through the electrode pad 5G In contrast, on the MEMS sensor mounting area S, a die attach metalized layer is not formed and the third substrate 13 that is a package material is exposed. In FIG. 6, the die attach metalized layer 4 and electrode pads 5 are shown with hatching applied thereto.

The MEMS sensor 2 is a device in which sensor components formed by micro-fabrication with use of MEMS (Micro Electro Mechanical Systems), such as pressure sensors, acceleration sensors, or angular velocity sensors, for example, are integrated on a single base material (a silicon substrate, a glass substrate, an organic material, or the like). The MEMS sensor 2 is adhered and fixed onto the third substrate 13 which is exposed on the MEMS sensor mounting area S, by a resin adhesive 6 such as an epoxy-based die bonding resin, a silicone-based die bonding resin, or a fluorine-based die bonding resin, for example.

Each of the first to third substrates 11 to 13 constituting the main body section 10 of the MEMS sensor package 1 is constituted by a material having an approximately equivalent linear expansion coefficient to that of a base material of the MEMS sensor 2, for example, a ceramic substrate, a silicon substrate, a high heat resistant polyimide film, or the like. It is ideal that the linear expansion coefficient of the first to third substrates 11 to 13 is the same as the linear expansion coefficient of the base material of the MEMS sensor 2. However, it is preferable that the difference between it and the linear expansion coefficient of the base material of the MEMS sensor 2 be within 5 ppm/° C.

The driving IC 3 is a semiconductor driving control circuit which controls driving of the MEMS sensor 2. The driving IC 3 is adhered and fixed on the die attach metalized layer 4 formed on the driving IC mounting area I, by an electrically-conductive resin adhesive 7. The electrically-conductive resin adhesive 7 is, for example, an epoxy-based die bonding resin, an urethane-based resin, a silicone-based resin, an acrylic-based resin, or the like, which is mixed with electrically-conductive fillers,

On the second substrate 12 which is exposed in the opening portion 11a of the first substrate 11, a plurality of electrode pads 5 which is connected to the MEMS sensor 2 and the driving IC 3 is formed. The MEMS sensor 2, the driving IC 3, and the plurality of electrode pads 5 are electrically connected to each other by Au wires 8. The MEMS sensor 2 and the driving IC 3 including the wire bonding portions are sealed by a sealing resin 9. As the sealing resin 9, for example, an epoxy-based die bonding resin is used.

The surface (the back surface of the MEMS sensor package) on the opposite side to the mounting surface 13a of the third substrate 13 is an SMD surface 13b which is mounted on an external circuit. On the SMD surface 13b, a plurality of electrode pads for external connection (not shown) is formed. The plurality of electrode pads for external connection and the plurality of electrode pads 5 provided in the receiving concave portion 10a are conductively connected to each other through side electrodes 13c (FIG. 1) provided on the side surface of the third substrate 13.

The MEMS sensor package 1 described above is manufactured as follows.

First, the MEMS sensor 2 and the driving IC 3 are mounted on the mounting surface 13a of a main body section 10′ shown in FIG. 6. Mounting of the MEMS sensor 2 is performed by applying the resin adhesive 6 which is made of, for example, an epoxy-based die bonding resin, a silicone-based die bonding resin, a fluorine-based die bonding resin, or the like on a bonding surface of the MEMS sensor 2 or the MEMS sensor mounting area S and then adhering and fixing the MEMS sensor 2 to the MEMS sensor mounting area S. At the time of the adhesion and fixing, the resin adhesive 6 is cured by heating. However, since a difference in linear expansion coefficient between the base material of the MEMS sensor 2 and the third substrate 13 which is exposed on the MEMS sensor mounting area S is small, even if thermal strain arises in the MEMS sensor 2 and the third substrate 13, thermal strain stress that the MEMS sensor 2 receives from the third substrate 13 is small, so that it does not adversely affect the performance of the MEMS sensor 2. On the other hand, mounting of the driving IC 3 is performed by applying the electrically-conductive resin adhesive 7 onto a bonding surface of the driving IC 3 or the die attach metalized layer 4 formed on the driving IC mounting area I and then adhering and fixing the driving IC 3 to the driving IC mounting area I. As the electric ally-conductive resin adhesive 7, for example, an epoxy-based die bonding resin or the like which is mixed with electrically-conductive fillers is used. Since the portion 4a of the die attach metalized layer 4 is extended and connected to the electrode pad 5G which is connected to the ground terminal, external noise on the driving IC 3 flows to a ground through the die attach metalized layer 4, so that the effect of noise on the driving IC 3 can be reduced. The mounting of the MEMS sensor 2 and the driving IC 3 is performed in random order.

Next, the MEMS sensor 2 and the driving IC 3 are connected to each other by wire bonding and the electrode pads of the MEMS sensor 2 and the driving IC 3 and the electrode pads 5 on the main body section 10 side are connected to each other by wire bonding. Subsequently, the receiving concave portion 10a of the main body section 10 is filled with the sealing resin 9 made of, for example, an epoxy-based die bonding resin, so that the MEMS sensor 2 and the driving IC 3 including the wire bonding portions are sealed by the sealing resin 9. Then, the lid member 20 is adhered and fixed on the upper surface of the main body section 10 so as to cover the receiving concave portion 10a filled with the sealing resin 9.

By the above, the MEMS sensor package 1 shown in FIGS. 1 to 4 is completed. The MEMS sensor package 1 after completion can be mounted on the external circuit through the electrode pads for external connection provided on the back surface of the third substrate 13.

As described above, in this embodiment, since a die attach metalized layer is not formed on the MEMS sensor mounting area S and the MEMS sensor 2 is adhered and fixed onto the third substrate 13, even if thermal strain arises in the MEMS sensor 2 and the third substrate 13 at the time of the adhesion and fixing of the MEMS sensor 2, thermal strain stress that the MEMS sensor 2 receives from the third substrate 13 is small, so that it does not deteriorate the performance of the MEMS sensor 2. Then, since the die attach metalized layer 4 is formed on the driving IC mounting area I to which the driving IC 3 is adhered and fixed, external noise on the driving IC 3 can be eliminated through the die attach metalized layer 4. Accordingly, even if the MEMS sensor 2 and the driving IC 3 are provided on the same mounting surface 13a, the high-performance MEMS sensor package 1 can be realized.

The invention can be applied to an MEMS sensor package having a structure in which an MEMS sensor is mounted on the same mounting surface as that of a driving IC.

It should be understood by those skilled in the art that various modifications, combinations, sub-combinations and alterations may occur depending on design requirements and other factors insofar as they are within the scope of the appended claims of the equivalents thereof.

What is claimed is:

1. An MEMS sensor package comprising: an MEMS sensor and a driving IC that controls driving of the MEMS sensor, which are fixed to the same mounting surface made of a given package material,
wherein an MEMS sensor mounting area and a driving IC mounting area are set on the mounting surface,
a die attach metalized layer is formed on a package material of the driving IC mounting area, and
the driving IC is mounted on the die attach metalized layer, and the MEMS sensor is mounted on a package material of the MEMS sensor mounting area.

2. The MEMS sensor package according to claim 1, wherein the die attach metalized layer is connected to a ground.

3. The MEMS sensor package according to claim 1, wherein the package material is a material having an equivalent linear expansion coefficient to that of a base material of the MEMS sensor.
